(19) United States
(12) Patent Application Publication
(10) Pub. No.: US 2009/0226612 A1
(43) Pub. Date: Sep. 10, 2009

(54) ALKALINE EARTH METAL CONTAINING PRECURSOR SOLUTIONS

(76) Inventors: Satoko Ogawa, Tsuchiura (JP); Christian Dussarrat, Wilmington, DE (US)

Correspondence Address: AIR LIQUIDE;Intellectual Property, 2700 POST OAK BOULEVARD, SUITE 1800, HOUSTON, TX, 77056, US

(21) Appl. No.: 12/260,256

(22) Filed: Oct. 29, 2008

Related U.S. Application Data
(60) Provisional application No. 60/983,441, filed on Oct. 29, 2007.

(51) Int. Cl. C23C 16/18; C09D 5/00

(52) U.S. Cl. 427/252; 106/1.25

(57) ABSTRACT

Methods and compositions for depositing a film on one or more substrates include providing a reactor with at least one substrate disposed in the reactor. A liquid precursor solution is provided, where the liquid precursor solution comprises a solid precursor and an aromatic solvent. The solid precursor has the general formula:

M(RₘCp)₂Lₙ;

wherein M is an alkaline earth metal, and each R is independently either H or a C1-C4 linear, branched, or cyclic alkyl group. L is a Lewis base; m is 2, 3, 4, or 5; and n is 0, 1, or 2. The aromatic solvent comprises at least one aromatic ring, and has a greater boiling point than the melting point of the solid precursor. The liquid precursor solution is vaporized to form a precursor solution vapor, and the vapor is introduced into the reactor. At least part of the vapor is deposited onto the substrate to form an alkaline earth metal containing film.

### CROSS REFERENCE TO RELATED APPLICATIONS

The present application claims the benefit of U.S. Provisional Application Ser. No. 60/983,441, filed Oct. 29, 2007, herein incorporated by reference in its entirety for all purposes.

### BACKGROUND

1. Field of the Invention

This invention relates generally to the field of semiconductor, photovoltaic, flat panel or LCD-TFT device fabrication.

2. Background of the Invention

New dielectric thin films which have as a material property a high dielectric constant (“high-k films”) are becoming more necessary, as the overall device size decreases in the manufacture of semiconductor, photovoltaic, flat panel, or LCD-TFT type devices. High-k films are particularly useful to form capacitors, which may store and discharge electrical charge for the device.

High-k films are normally formed and/or deposited onto a substrate using the well known chemical vapor deposition (CVD) or Atomic Layer Deposition (ALD) manufacturing processes. There are many variations of the CVD and ALD processes but generally, these methods involve the introduction of at least one precursor (which contains the atoms desired to be deposited) into a reactor, where the precursor then reacts and/or decomposes onto a substrate in a controlled fashion to form a thin film. Generally, precursors are desired to be in a vapor form for the deposition, so in the case of liquid based precursors (or solid precursors in liquid suspension), it may be necessary to vaporize the precursors prior to their introduction into the reactor. Vaporization is generally accomplished with vaporizers or bubblers located upstream from the precursor injection point on the reactor.

While numerous materials have been investigated to form high-k films through CVD or ALD methods, solid alkaline earth metal, particularly strontium and barium, based precursors show promise. Most alkaline earth metal precursors can be characterized has having low vapor pressure, and high melting points (e.g. solid at room temperature), and very low volatility. These properties can lead to difficulty in delivering the precursors to the reactor, as the solid precursors may clog the supply lines or the vaporizers.

Solvents commonly utilized in precursor solutions, such as tetrahydrofurane (THF), are not necessarily compatible with the extreme low volatility of the alkaline earth metal precursors, and when they are used, the solvents will quickly vaporize before the precursor, easily reaching the solubility limit and leading to condensation of the precursor in the reactor inlet, or clogging of the vaporizer.

Consequently, there exists a need for alkaline earth metal precursor solutions which are easily deliverable for deposition methods.

### BRIEF SUMMARY

Embodiments of the present invention provide novel methods and compositions for the deposition of a film on a substrate. In general, the disclosed compositions and methods utilize a precursor mixture of a solid precursor and an aromatic solvent.

In an embodiment, a method for depositing a film on one or more substrates comprises providing a reactor with at least one substrate disposed in the reactor. A liquid precursor solution is provided, where the liquid precursor solution comprises a solid precursor and an aromatic solvent. The solid precursor has the general formula:

M(RₘCp)₂Lₙ;

wherein M is an alkaline earth metal, and each R is independently either H or a C1-C4 linear, branched, or cyclic alkyl group. L is a Lewis base; m is 2, 3, 4, or 5; and n is 0, 1, or 2. The aromatic solvent comprises at least one aromatic ring, and has a greater boiling point than the melting point of the solid precursor. The liquid precursor solution is vaporized to form a precursor solution vapor, and the vapor is introduced into the reactor. At least part of the vapor is deposited onto the substrate to form an alkaline earth metal containing film.

In another embodiment, a composition comprises both a solid precursor and an aromatic solvent. The solid precursor has the general formula:

M(RₘCp)₂Lₙ;

wherein M is an alkaline earth metal, and each R is independently either H or a C1-C4 linear, branched, or cyclic alkyl group. L is a Lewis base; m is 2, 3, 4, or 5; and n is 0, 1, or 2. The aromatic solvent comprises at least one aromatic ring, and has a greater boiling point than the melting point of the solid precursor.

Other embodiments of the current invention may include, without limitation, one or more of the following features:
the aromatic solvent comprises a solvent of the general formula

CₐR_{b}N_{c}O_{d}
wherein each R is independently selected from: H; a C1-C6 linear, branched, or cyclic alkyl or aryl group; an amino substituent such as NR¹R² or NR¹R²R³, where R¹, R² and R³ are independently selected from H, and a C1-C6 linear, branched, or cyclic alkyl or aryl group; and an alkoxy substituent such as OR⁴, or OR⁵R⁶ where R⁴, R⁵ and R⁶ are independently selected from H, and a C1-C6 linear, branched, or cyclic alkyl or aryl group;
   a is 4 or 6;
   b is 4, 5, or 6;
   c is 0 or 1; and
   d is 0 or 1;
   the aromatic solvent is selected from one of toluene; mesitylene; phenetol; octane; xylene; ethylbenzene; propylbenzene; ethyltoluene; ethtoxybenzene; pyridine; and mixtures thereof;
   the Lewis base is selected from one of tetrahydrofuran (THF); dioxane; diethoxyethane; and pyridine;
   the alkaline earth metal is barium or strontium;
   a reaction gas is introduced into the reactor, and the reaction gas is reacted with the precursor vapor solution prior to or concurrently with the deposition;
   the reaction gas is an oxidizing agent;
   the reaction gas is selected from one of O₂; O₃; H₂O; H₂O₂; NO; NO₂; and radical species and mixtures thereof;
   the deposition is either a chemical vapor deposition (CVD) or an atomic layer deposition (ALD);
   the deposition is performed at a temperature between about 50° C. and about 600° C., preferably between about 200° C. and about 500° C.;
   the deposition is performed at a pressure between about 0.0001 torr and about 1000 torr, preferably between about 0.1 torr and about 10 torr; and
   the solid precursor is selected from one of: Sr(iPr₃Cp)₂, Sr(iPr₃Cp)₂(THF), Sr(iPr₃Cp)₂(THF)₂, Sr(iPr₃Cp)₂(dimethylether), Sr(iPr₃Cp)₂(dimethylether)₂, Sr(iPr₃Cp)₂(diethylether), Sr(iPr₃Cp)₂(diethylether)₂, Ba(iPr₃Cp)₂, Ba(iPr₃Cp)₂(THF), Ba(iPr₃Cp)₂(THF)₂, Ba(iPr₃Cp)₂(dimethylether), Ba(iPr₃Cp)₂(dimethylether)₂, Ba(iPr₃Cp)₂(diethylether), Ba(iPr₃Cp)₂(diethylether)₂ Ba(tBu₃Cp)₂ Ba(tBu₃Cp)₂(THF), Ba(tBu₃Cp)₂(THF)₂, Ba(tBu₃Cp)₂(dimethylether), Ba(tBu₃Cp)₂(dimethylether)₂, Ba(tBu₃Cp)₂(diethylether), and Sr(tBu₃Cp)₂(diethylether)₂.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to particular system components. This document does not intend to distinguish between components that differ in name but not function.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl, isobutyl, etc. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “Pr,” refers to a propyl group; the abbreviation, “iPr,” refers to an isopropyl group; the abbreviation “n-Pr” refers to an n-propyl group, “Bu” refers to a butyl group, “n-Bu” refers to an n-butyl group, “t-Bu” refers to a tert-butyl group, “H” refers to a hydrogen atom, and “Cp” refers to a cyclopentadienyl ligand.

### DESCRIPTION OF PREFERRED EMBODIMENTS

Embodiments of the present invention provide novel methods and compositions for the deposition of a film on a substrate. In general, the disclosed compositions and methods utilize a precursor mixture of a solid precursor and an aromatic solvent.

In some embodiments, a liquid alkaline earth metal precursor solution is provided to a reactor for deposition onto a substrate. The solution contains a solid alkaline earth metal precursor and a solvent. Proper combinations of the precursor and solvent may ensure smooth delivery and prevent clogging of the distribution system vaporizer or supply line from the vaporization of the solution. In particular, by combining the precursor with a solvent which has a boiling point greater than the melting point of the solid precursor (where the vaporization point of the solvent is also greater than that of the solid precursor) such distribution problems may be reduced or limited, as there will not be condensation or agglomeration of the solid in the feed lines, the vaporizer, or the inlet to the reactor.

In some embodiments, the solid precursor may have one of the general formulas:

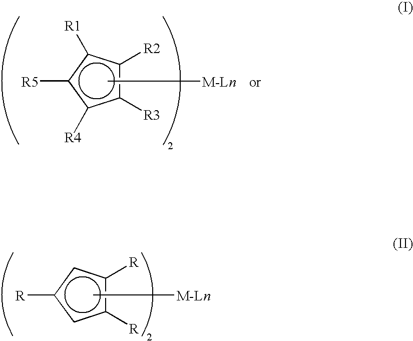

where M is strontium or barium; each R is independently selected from H, Me, Et, n-Pr, i-Pr, n-Bu, or t-Bu; m is 2, 3, 4, or 5; n is 0, 1, or 2; and L is an oxygen, nitrogen or phosphorus containing Lewis base.

In some embodiments, the solvent is an aromatic solvent characterized in that the solvent has at least one aromatic ring. It has been determined that aromatic molecules are particularly suitable as solvents for alkaline earth metal precursors, in terms of solubility while having a vaporization temperature greater than that of tetrahydrofurane or pentane, which are sometimes used as precursor solvents.

In some embodiments, the aromatic solvent may be one of the following:

TABLE 1
Examples of solvents

| | Formula | b.p. | Density | Viscosity |
|---|---|---|---|---|
| Name | (F.W.) | [C.] | [g/cm3] | [cP] @25 C. |
| Octane | C₈H₈ (114.23) | 125 | 0.7 | 0.51 |
| Toluene | C₆H₅CH₃ (92.14) | 111 | 0.87 | 0.54 |
| Xylene | C₆H₄(CH₃)₂ (106.16) | 138.5 | 0.86 | 0.6 |
| Mesitylene | C₆H₃(CH₃)₃ (120.2) | 165 | 0.86 | 0.99 |
| Ethylbenzene | C₆H₅C₂H₅ (106.17) | 136 | 0.87 | 0.67 |
| Propylbenzene | C₆H₅C₃H₇ (120) | 159 | 0.86 | 0.81 |
| Ethyl toluene | C₆H₄(CH₃)(C₂H₅) | 160 | 0.86 | 0.63 |
| | (120.19) | | | |
| Ethoxybenzene | C₆H₅OC₂H₅ (122.17) | 173 | 0.96 | 1.1 |
| Pyridine | C₆H₅N (79.1) | 115 | 0.98 | 0.94 |

The disclosed precursor solutions may be deposited to form a thin film using any deposition methods known to those of skill in the art. Examples of suitable deposition methods include without limitation, conventional CVD, low pressure chemical vapor deposition (LPCVD), atomic layer deposition (ALD), pulsed chemical vapor deposition (P-CVD), plasma enhanced atomic layer deposition (PE-ALD), or combinations thereof.

In an embodiment, a precursor solution vapor may be introduced into a reactor. The precursor solution vapor may be produced by vaporizing the liquid precursor solution, through a conventional vaporization step such as direct vaporization, distillation, or by bubbling an inert gas (e.g. N₂, He, Ar, etc.) into the precursor solution and providing the inert gas plus precursor mixture as a precursor vapor solution to the reactor. Bubbling with an inert gas may also remove any dissolved oxygen present in the precursor solution.

The reactor may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates on to which the thin films will be deposited. The one or more substrates may be any suitable substrate used in semiconductor, photovoltaic, flat panel or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium or gold) may be used.

In some embodiments, in addition to the precursor vapor solution, a reaction gas may also be introduced into the reactor. The reaction gas may be one of oxygen, ozone, water, hydrogen peroxide, nitric oxide, nitrogen dioxide, radical species of these, as well as mixtures of any two or more of these. In some embodiments, the precursor vapor solution and the reaction gas may be introduced into the reactor sequentially (as in ALD) or simultaneously (as in CVD).

In some embodiments, the temperature and the pressure within the reactor are held at conditions suitable for ALD or CVD depositions. For instance, the pressure in the reactor may be held between about 0.0001 and 1000 torr, or preferably between about 0.1 and 10 torr, as required per the deposition parameters. Likewise, the temperature in the reactor may be held between about 50° C. and about 600° C., preferably between about 200° C. and about 500° C.

In some embodiments, the precursor vapor solution and the reaction gas, may be pulsed sequentially or simultaneously (e.g. pulsed CVD) into the reactor. Each pulse of precursor may last for a time period ranging from about 0.01 seconds to about 10 seconds, alternatively from about 0.3 seconds to about 3 seconds, alternatively from about 0.5 seconds to about 2 seconds. In another embodiment, the reaction gas may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds.

### EXAMPLES

The following non-limiting examples are provided to further illustrate embodiments of the invention. However, the examples are not intended to be all inclusive and are not intended to limit the scope of the inventions described herein.

### Example 1

Sr(iPr₃Cp)₂(THF)₂ can be dissolved in, toluene, xylene, mesitylene, ethoxybenzene, propylbenzene with high solubility (over 0.1 mol/L) at room temperature. This strontium precursor's vapor pressure is above 1 torr at 180° C. and its melting point is 94° C. THF's boiling point is below this point and has been found to lead to polymerization near the vaporization point. The boiling point of each of these solvents is higher than the melting point of the strontium precursor. This combination can make liquid delivery smooth and prevent clogging by vaporization of the solvent in the supply line and the vaporizer.

While embodiments of this invention have been described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method for depositing a film on to one or more substrates, comprising:
a) providing a reactor, and at least one substrate disposed in the reactor;
b) providing a liquid precursor solution, wherein the liquid precursor solution comprises:
1) a solid precursor of the general formula:
M(RₘCp)₂Lₙ
wherein:
M is an alkaline earth metal;
each R is independently selected from H, and a C1-C4 linear, branched, or cyclic alkyl group;
m is one of 2, 3, 4, or 5;
n is one of 0, 1 or 2; and
L is a Lewis base; and
2) an aromatic solvent, wherein the aromatic solvent comprises at least one aromatic ring; and wherein the aromatic solvent has a boiling point greater than the melting point of the solid precursor; and
c) vaporizing the liquid precursor solution to form a precursor solution vapor;
d) introducing the precursor solution vapor into the reactor; and
e) depositing at least part of the precursor vapor solution onto the substrate to form an alkaline earth metal containing film.

2. The method of claim 1, wherein the aromatic solvent comprises a solvent of the general formula:
CₐR_{b}N_{c}O_{d}
wherein:
each R is independently selected from: H; a C1-C6 linear, branched, or cyclic alkyl or aryl group; an amino substituent such as NR¹R² or NR¹R²R³, where R¹, R² and R³ are independently selected from H, and a C1-C6 linear, branched, or cyclic alkyl or aryl group; and an alkoxy substituent such as OR⁴, or OR⁵R⁶ where R⁴, R⁵ and R⁶ are independently selected from H, and a C1-C6 linear, branched, or cyclic alkyl or aryl group;
a is 4 or 6;
b is 4, 5, or 6;
c is 0 or 1: and
d is 0 or 1.

3. The method of claim 2, wherein the aromatic solvent comprises at least one member selected from the group consisting of: toluene; mesitylene; phenetol; octane; xylene; ethylbenzene; propylbenzene; ethyltoluene; ethtoxybenzene; pyridine; and mixtures thereof.

4. The method of claim 1, wherein the Lewis base comprises at least one member selected from the group consisting of: tetrahydrofuran; dioxane; diethoxyethane; and pyridine.

5. The method of claim 1, wherein the alkaline earth metal is barium or strontium.

6. The method of claim 1, further comprising:
a) introducing a reaction gas into the reactor;
b) reacting the reaction gas with the precursor vapor solution prior to or concurrently with the deposition of at least part of the precursor vapor solution onto the substrate.

7. The method of claim 6, wherein the reaction gas comprises an oxidizing agent.

8. The method of claim 7, wherein the reaction gas comprises at least one member selected from the group consisting of: O₂; O₃; H₂O; H₂O₂; NO, NO₂; and radical species and mixtures thereof.

9. The method of claim 1, further comprising depositing at least part of the precursor vapor solution through a chemical vapor deposition (CVD) or an atomic layer deposition (ALD) process.

10. The method of claim 9, wherein the deposition is performed at a temperature between about 50° C. and about 600° C.

11. The method of claim 10, wherein the temperature is between about 200° C. and about 500° C.

12. The method of claim 9, wherein the deposition is performed at a pressure between about 0.0001 torr and about 1000 torr.

13. The method of claim 12, wherein the pressure is between about 0.1 torr and about 10 torr.

14. The method of claim 1, wherein the solid precursor comprises at least one member selected from the group consisting of: Sr(iPr₃Cp)₂, Sr(iPr₃Cp)₂(THF), Sr(iPr₃Cp)₂(THF)₂, Sr(iPr₃Cp)₂(dimethylether), Sr(iPr₃Cp)₂(dimethylether)₂, Sr(iPr₃Cp)₂(diethylether), Sr(iPr₃Cp)₂(diethylether)₂, Ba(iPr₃Cp)₂, Ba(iPr₃Cp)₂(THF), Ba(iPr₃Cp)₂(THF)₂, Ba(iPr₃Cp)₂(dimethylether), Ba(iPr₃Cp)₂(dimethylether)₂, Ba(iPr₃Cp)₂(diethylether), Ba(iPr₃Cp)₂(diethylether)₂ Ba(tBu₃Cp)₂ Ba(tBu₃Cp)₂(THF), Ba(tBu₃Cp)₂(THF)₂, Ba(tBu₃Cp)₂(dimethylether), Ba(tBu₃Cp)₂(dimethylether)₂, Ba(tBu₃Cp)₂(diethylether), and Sr(tBu₃Cp)₂(diethylether)₂.

15. A composition comprising a solid precursor and an aromatic solvent, wherein:
a) the liquid precursor solution comprises:
1) a solid precursor of the general formula:
M(RₘCp)₂Lₙ
wherein:
M is an alkaline earth metal;
each R is independently selected from H, and a C1-C4 linear, branched, or cyclic alkyl group;
m is one of 2, 3, 4, or 5;
n is one of 0, 1 or 2; and
L is a Lewis base; and
b) the aromatic solvent comprises at least one aromatic ring; and wherein the aromatic solvent has a boiling point greater than the melting point of the solid precursor;

16. The composition of claim 15, wherein the aromatic solvent comprises a solvent of the general formula:
CₐR_{b}N_{c}O_{d}
wherein:
each R is independently selected from: H; a C1-C6 linear, branched, or cyclic alkyl or aryl group; an amino substituent such as NR¹R² or NR¹R²R³, where R¹, R² and R³ are independently selected from H, and a C1-C6 linear, branched, or cyclic alkyl or aryl group; and an alkoxy substituent such as OR⁴, or OR⁵R⁶ where R⁴, R⁵ and R⁶ are independently selected from H, and a C1-C6 linear, branched, or cyclic alkyl or aryl group;
a is 4 or 6;
b is 4, 5, or 6;
c is 0 or 1; and
d is 0 or 1.

17. The composition of claim 16, wherein the aromatic solvent comprises at least one member selected from the group consisting of: toluene; mesitylene; phenetol; octane; xylene; ethylbenzene; propylbenzene; ethyltoluene; ethtoxybenzene; pyridine; and mixtures thereof.

18. The composition of claim 15, wherein the Lewis base comprises at least one member selected from the group consisting of: tetrahydrofuran; dioxane; diethoxyethane; and pyridine.

19. The composition of claim 15, wherein the solid precursor comprises at least one member selected from the group consisting of: Sr(iPr₃Cp)₂, Sr(iPr₃Cp)₂(THF), Sr(iPr₃Cp)₂(THF)₂, Sr(iPr₃Cp)₂(dimethylether), Sr(iPr₃Cp)₂(dimethylether)₂, Sr(iPr₃Cp)₂(diethylether), Sr(iPr₃Cp)₂(diethylether)₂, Ba(iPr₃Cp)₂, Ba(iPr₃Cp)₂(THF), Ba(iPr₃Cp)₂(THF)₂, Ba(iPr₃Cp)₂(dimethylether), Ba(iPr₃Cp)₂(dimethylether)₂, Ba(iPr₃Cp)₂(diethylether), Ba(iPr₃Cp)₂(diethylether)₂ Ba(tBu₃Cp)₂, Ba(tBu₃Cp)₂(THF), Ba(tBu₃Cp)₂(THF)₂, Ba(tBu₃Cp)₂(dimethylether), Ba(tBu₃Cp)₂(dimethylether)₂, Ba(tBu₃Cp)₂(diethylether), and Sr(tBu₃Cp)₂(diethylether)₂.

20. A strontium or barium-containing thin film-coated substrate comprising the product of the method of claim 1.
